(19) United States
(12) Patent Application Publication
(10) Pub. No.: US 2024/0102743 A1
(43) Pub. Date: Mar. 28, 2024

(54) PERFORMANCE ENHANCEMENT IN THERMAL SYSTEM WITH POROUS SURFACES

(71) Applicants: ASELSAN ELEKTRONIK SANAYI VE TICARET ANONIM SIRKETI, Ankara (TR); APAK ENDUSTRI MUHENDISLIK MAKINE SANAYI VE TICARET LIMITED SIRKETI, Eskisehir (TR); SABANCI UNIVERSITESI NANOTEKNOLOJI ARASTIRMA VE UYGULAMA MERKEZI, Istanbul (TR); SABANCI UNIVERSITESI, Istanbul (TR)

(72) Inventors: Ali KOSAR, Istanbul (TR); Ismet Inonu KAYA, Istanbul (TR); Abdolali Khalili SADAGHIANI, Istanbul (TR); Alper APAK, Eskisehir (TR); Ahmet Muhtar APAK, Eskisehir (TR); Murat PARLAK, Ankara (TR); Umur TASTAN, Ankara (TR); Mehmet BONCU, Ankara (TR)

(73) Assignees: ASELSAN ELEKTRONIK SANAYI VE TICARET ANONIM SIRKETI, Ankara (TR); APAK ENDUSTRI MUHENDISLIK MAKINE SANAYI VE TICARET LIMITED SIRKETI, Eskisehir (TR); SABANCI UNIVERSITESI NANOTEKNOLOJI ARASTIRMA VE UYGULAMA MERKEZI, Istanbul (TR); SABANCI UNIVERSITESI, Istanbul (TR)

(21) Appl. No.: 18/253,792

(22) PCT Filed: Nov. 24, 2020
(86) PCT No.: PCT/TR2020/051161

§ 371 Date: May 22, 2023

(51) Int. Cl. F28D 15/04; F28D 15/02

(52) U.S. Cl. CPC F28D 15/046; F28D 15/0233

(57) ABSTRACT

Optimized 3-D graphene structures used to enhance thermal performance of the thermal systems such as vapor chambers are provided. The porosity of the wick/porous structure has a critical effect on the efficiency of a vapor chamber system. Graphene coating provides high thermal conductivity, and it has a high porous structure, which is favorable for vapor chamber devices.

### CROSS REFERENCE TO RELATED APPLICATIONS

This application is the national stage entry of International Application No. PCT/TR2021/051161 filed Nov. 24, 2020, the entire contents of which are incorporated by reference herein.

### TECHNICAL FIELD

The present disclosure is related to using optimized 3-D graphene structures to enhance thermal performance of the vapor chambers. The porosity of the wick/porous structure has a critical effect on the efficiency of a vapor chamber system. Graphene coating provides high thermal conductivity, and it has a high porous structure, which is favorable for vapor chamber devices.

### BACKGROUND

A vapor chamber cooling system, also known as a vapor chamber, is a cooling technology that uses the liquid-vapor phase change phenomena and capillary effect. Mobile devices, LED cooling, high power RF/MW amplifier cooling and server cooling are some of the immediate markets for vapor chamber devices. The use of metals, mostly copper, is common for the walls and the main structures of the vapor chamber. Typical vapor chamber operates between a bottom and a top cover being in contact with the heat source and condenser, respectively. The liquid used in the vapor chamber absorbs heat from the heat source and turns into vapor. Afterwards, as the vapor reaches the condenser (cold side/end), it becomes liquid and is transported back to the heat source side through the wick structure. The porosity of the wick structure has a critical effect on the efficiency of a vapor chamber system.

In known art, on the inner surfaces of the vapor chamber, porous wick structures are used for capillary effect purposes. The most used technique in forming the porous wick structure is the bonding of metal powders, called sintering, to each other and to the surface by a suitable process. This porous wick structure allows the liquid used for heat transfer to move in all directions despite the gravitational effect; it allows flow through the empty pores. This effect is like the transportation of water from roots to leaves in plants. In the vapor chamber structures, the porosity of the porous structure is optimized, and the thermal conductivity of the material used for the porous structure has a very high effect on the operational efficiency. Existing designs for vapor chambers use a copper powder to form a wick structure. The copper can be sintered to form a thicker coat for high process temperatures. Other examples use a lithography process to form wick structures on the inside walls of the vapor chambers. However, the sintering and lithography processes might have long process times and high costs.

Recently, thanks to the unique properties and interesting capabilities, graphene has received much attention. Graphene consisting of sp2-hybridized carbon atoms in two-dimensional hexagonal lattice has been a promising alternative for many fields owing to its extraordinary physical and mechanical properties such as high thermal and electrical conductivity, noteworthy optical transmittance, superior chemical stability and high flexibility.

There are several inventions suggesting a graphene layer/sheet coating inside and outside of the vapor chamber to enhance heat transfer from heating/cooling part to the vapor chamber.

Patent application U.S. Pat. No. 9,412,925B2 is related to high-power LED lamp cooling device and method for manufacturing the same. Chen et al. propose a device comprising a graphene thermal conductive greaseon layer used in heat transfer process.

Patent application US20180347921A1 is related using a conductive sheet that includes graphene for thermal conductivity and for grounding. Morrison et al. propose a computing device comprising graphene layers used for thermal and electrical conductivity.

U.S. patent application Ser. No. 10/146,278B2 is related to thermal spreader spanning two (or more) housings. North et al. propose a computing device comprising a thermal spreader comprising graphene sheets used in heat transfer.

Patent application US20190048476A1 is related to coating for a vapor chamber. Wu et al. propose a vapor chamber, in which a silica derived carbon nanotube (CNT) aerogel coating is applied on the nickel coating on the inside walls of the metallic housing. In their proposed system, CNT coating was coated on top of the Nickel film.

Patent application US20160109912A1 is related to heat dissipation structure for mobile device. Shen proposed a heat dissipation structure for a mobile device working with a vapor chamber, which was coated with pieces of graphene or graphite, without mentioning a 3-D body.

Patent application CN108006798 (A) is related to floor heating device based on graphene heat conduction and radiation of far infrared ray. Haijun and Jixiao proposed a device for floor heating including a vapor chamber. In their invention, they stated the usage of graphene sheets.

A similar system was proposed by Zhenzhong in a utility model application CN205579718 (U). The utility model discloses a floor heating structure based on graphite alkene heat-conducting plate. Graphene thin film coating on copper with groove pattern was mentioned in his application.

Another similar system was proposed by Fangxiang et at. in a utility model application CN206923216 (U). The utility model discloses a heat sink comprising a base plate graphene.

To the best knowledge of the inventors, no 3-D graphene porous coating has been proposed for vapor chamber applications. Most of the proposed techniques and systems work with graphene coated metallic surfaces. In this situation, one or more sheets of graphene are coated on the metallic surfaces. Although graphene has unique properties, its preparation typically results in cracks, wrinkling, defects, and mechanical problems when it is integrated into three dimensional applications.

Existing designs for vapor chambers have disadvantages of high thermal resistance, low cooling capacity and are orientation dependent.

To overcome this drawback in real life applications, graphene has been prepared in three dimensional forms such as aerogel, foam and sponge during the last decade. These forms have low mass density, large surface area, good mechanical stability, high thermal and electrical conductivity. Besides energy, sensing, detecting, tissue engineering, and environmental applications, three-dimensional (3D) graphene frameworks also have a potential in heat transfer enhancement because of their high thermal conductivity.

### SUMMARY

The idea is to use optimized 3-D graphene structure for thermal performance enhancement of the vapor chambers, wherein the said 3-D graphene structure meets the abovementioned requirements, eliminates all disadvantages, and brings additional benefits.

The main purpose of the invention is to enhance thermal performance of the vapor chambers using optimized 3-D graphene structures.

Another purpose of the invention is to provide a porous wick medium made from 3-D graphene structures, in which the structures are not sheets or layers of graphene, instead prepared in three dimensional forms such as aerogel, foam or sponge.

Another purpose of the invention is to decrease the thermal resistance of the system and increases the cooling performance of the vapor chamber by using graphene as porous wick medium that has thermal conductivity of k>2000 W/m·K.

Another purpose of the invention is to provide a porous wick medium for vapor chambers of which 3-D structure fabrication process does not detriment the base metallic surface structure and profile.

In order to fulfill the abovementioned purposes, the invention propose a 3-D (three-dimensional) graphene structure for use as a porous wick medium in thermal systems such as vapor chambers or heat pipes to enhance thermal performance.

In order to fulfill the abovementioned purposes, the invention propose a vapor chamber comprising: a metallic housing; and a porous wick medium coated on the inside walls of the metallic housing, wherein the porous wick medium comprises 3-D graphene structure.

The structural properties, characteristics and all benefits of the invention will be more clearly understood by reading the detailed description of the invention in conjunction with the below drawings. Therefore, the invention will be best appreciated by reading the detailed description in conjunction with the accompanying drawings.

### BRIEF DESCRIPTION OF THE DRAWINGS

FIG. 1 is a schematic of an example of vapor chamber enhanced with 3-D graphene structure.

FIG. 2 is another example of the proposed vapor chamber with 3-D graphene structures having different thicknesses.

FIG. 3 is another example of the proposed vapor chamber with pillar structures having (surrounded by) 3-D graphene structures.

FIG. 4 is a SEM image of a 3-D graphene structure sample.

### DETAILED DESCRIPTION OF THE INVENTION

Elements shown in the figures FIGS. are individually numbered, and the correspondence of these numbers are given as follows:
100 vapor chamber
101 metallic housing
102 3-D graphene structure
103 heat-in source
104 heat-out source
105 internal volume
106 vapor
107 liquid
108 primary thickness
109 secondary thickness
110 pillar

In this detailed description using optimized 3-D graphene structures and preferred embodiments are only described for clarifying the subject matter and in a non-limiting manner.

The invention relates to performance enhancement in thermal system with porous surfaces. The porosity of the wick/porous structure has a critical effect on the efficiency of thermal systems such as vapor chambers or heat pipes used in electronic devices. The invention is based on enhancing thermal performance of the vapor chambers or heat pipes using optimized 3-D graphene structures. Graphene coating provides high thermal conductivity, and it has a high porous structure, which is favorable for vapor chamber devices.

The invention proposes a porous 3-D graphene structure with pore sizes ranging from 1 μm to 1000 μm for use as a porous wick medium in thermal systems such as vapor chambers or heat pies to enhance thermal performance. In vapor chamber structures, the porosity of the porous structure is optimized, and the thermal conductivity of the material used for the porous structure has a very high effect on the operational efficiency. Preferred embodiment of invention proposes the use of 3-D graphene as porous building material in Vapor Chamber Cooling Systems. The aim of using graphene is to optimize the porosity of the porous structure, to optimize the biphilicity of the vapor chamber surfaces, and to provide higher thermal conductivity. The high thermal conductivity and mechanical strength of the graphene structure allow the porosity to be increased.

The present disclosure uses a porous 3-D graphene structure being fabricated in three dimensional forms such as aerogel, foam, and sponge on the inside wall of the vapor chamber to form the wick structure.

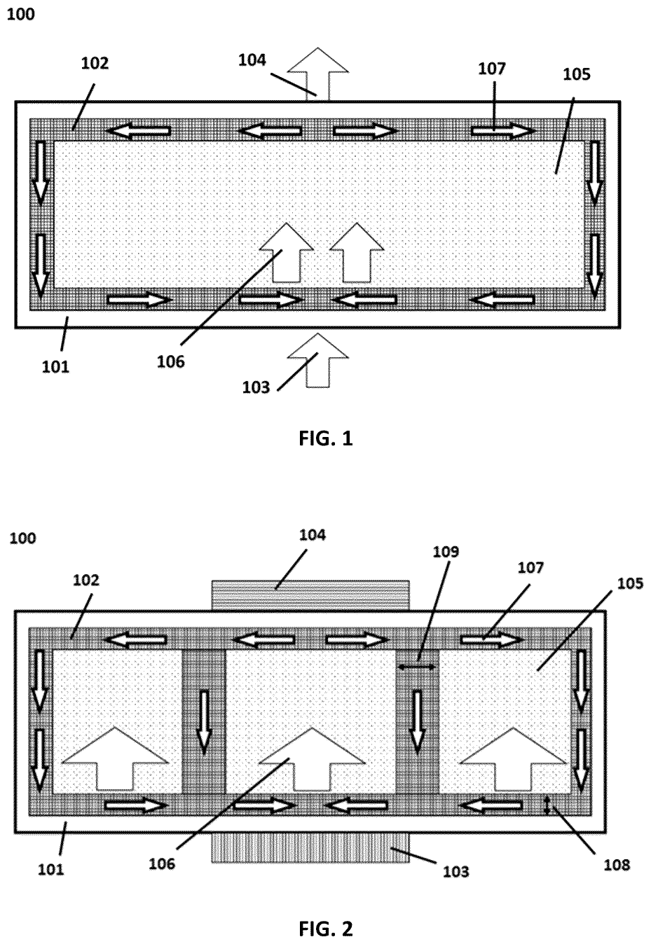

FIG. 1 illustrates schematic sectional view of an example vapor chamber (100) of the present disclosure. The vapor chamber (100) comprising a metallic housing (101); and 3-D graphene structure (102) as a porous wick medium coated on the inside walls of the metallic housing (101). The metallic housing (101) could be any conductive material such as Copper, Aluminum, Tungsten, and similar conductive metals. The 3-D graphene structure (102) has high porosity (high surface area), which enhances the performance of vapor chamber. As an example of application, the vapor chamber (100) could operate between a heat-in source (103) and a heat-out source (104). As an example, the heat-in source (103) could be any electronic device generating heat such as a processor.

In one embodiment, the vapor chamber (100) may have an internal volume (105). A portion of the internal volume (105) is partially filled with a wetting liquid before vacuum sealing. Being in contact with the heat-in source (103), the wetting liquid (coolant) is converted to vapor (106). The vapor (106) moves away from the heat-in source (103) and gets in contact with the heat-out source (104). The heat-out source (104) acts opposite to the heat-in source (103), by converting the vapor into liquid (107). The liquid (107) returns to replenish and rewet the wall in contact with the heat-in source (103).

As shown in FIG. 1, the 3-D graphene structure (102) has a certain primary thickness (108). In an actual 3D graphene structure (102), it could have the thicknesses between nm to hundreds of micrometers. The properties of 3-D graphene structure (102) such as high thermal conductivity and high porosity enhance the heat transfer performance of the device. In a preferred embodiment, the 3-D graphene structure (102) has a porosity in the range of 30% to 99% by volume. In a specific example shown in FIG. 1, the 3-D graphene structure (102) has minimum 93% porosity by volume. The abovementioned structure can be formed from an atomic layer to several atomic layers, giving rise to the thickness of one nanometer to several hundred nanometers to the skeleton. This thickness should not be confused with the total primary thickness (108) of the 3-D graphene structure (102).

3-D graphene structure (102) can be in different shapes with different pore sizes. FIG. 4 shows an SEM image of an example 3-D graphene structure (102) sample used as a porous wick medium in vapor chambers. The 3-D graphene structure (102) of wick medium can be in different shapes with different pore sizes.

The vapor chamber (100), comprising 3-D graphene structure (102) as a porous wick medium totally made of the graphene material. In known art, Copper (thermal conductivity of k=385 W/m·K) is the common material utilized in vapor chambers. Using graphene (thermal conductivity of k>2000 W/m·K) as porous material in vapor chambers dramatically decreases the thermal resistance of the system and increases the cooling performance of the vapor chamber (100). This means porous wick medium comprising 3-D graphene structure (102) with thinner thicknesses can outperform the existing conventional vapor chambers. This not only decreases the amount of required coolant in the vapor chamber (100), but also decreases vapor chamber's (100), size and weight. This is an important parameter, since system size is one of the main challenges in vapor chamber applications especially in mobile devices, which are a large and fast growing market for these devices.

Another embodiment of the invention is shown in FIG. 2. 3-D graphene structure (102) with a primary thickness (108) is coated on the inside walls of the metallic housing (101). Furthermore, internal volume (105) is divided into a number of chambers by 3-D graphene structure (102) with a secondary thickness (109) connecting to the 3-D graphene structure (102) with the primary thickness (108). The secondary thickness (109) is greater than the primary thickness (108) optionally. Preferably, 3-D graphene structure (102) with secondary thickness (109) are connected in a way that is perpendicular to the 3-D graphene structure (102) with primary thickness (108) where the heating sources are being in touch and is parallel to each other.

The thickness difference can have an enhancing effect on the vapor venting and liquid transport within the structure. The wicking effect and capillary pumping flow rate increases with the porous thickness. As a result, thicker or thinner can be used, porous structures at different locations.

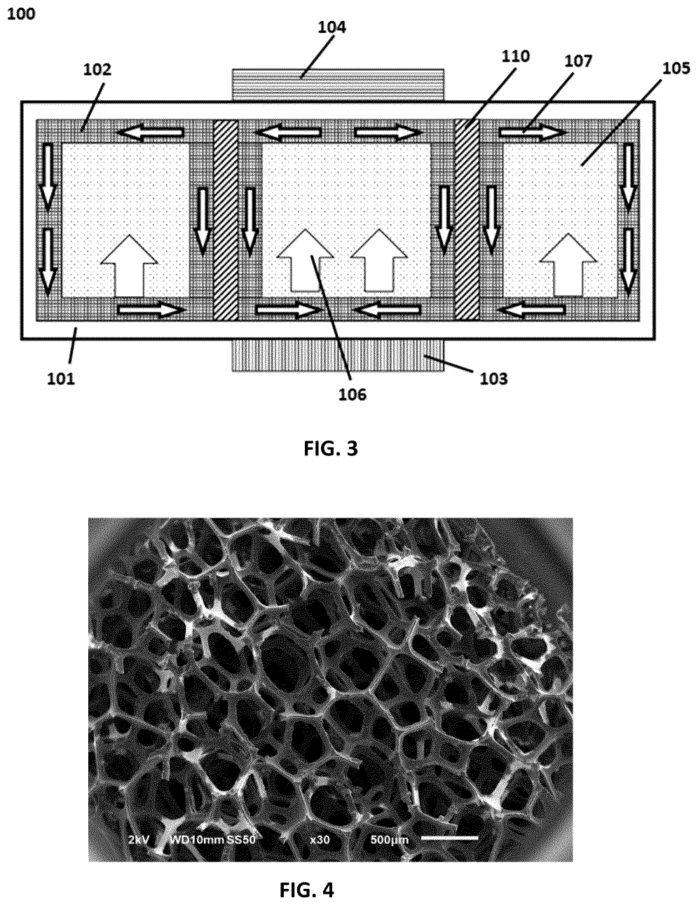

Another embodiment of the invention is shown in FIG. 3. In this embodiment internal volume (105) of metallic housing (101) is divided into a number of chambers by at least one pillar (110) connecting to the metallic housing (101). Preferably, the pillars (110) are connected in a way that is perpendicular to the walls where the heating sources are being in touch and is parallel to each other. 3-D graphene structure (102) as a porous wick medium is coated on the inside walls of these divided chambers.

Basically, these pillars represent protrusions, pits, grooves, dots, etc. There exist spacers (in different shapes and dimensions as stated in the previous sentence) in some of the available designs. One can adapt the proposed technology into these kinds of designs. The proposed technology has also enhancing effect on the operating of these devices.

The porous wick medium comprising 3-D graphene structure (102) prepared in three dimensional forms such as aerogel, foam, or sponge, which is not made from sheets or layers of graphene. In known art, some enhancement techniques proposed deposition of a layer or several layers of graphene, graphite or carbon nanotubes (CNT) sheets to increase the efficiency of the system. In those cases, graphene, graphite or CNTs are coated on an existing porous structure such as nickel or copper. In present disclosure a 3-D structure which is made (partially or fully) from graphene material is proposed. Also, the 3-D structure fabrication process does not detriment the base metallic surface structure and profile. In existing vapor chambers, powder sintering destroys the micro/nanostructures fabricated on the walls. This is one of the disadvantages of such processes.

What is claimed is:

1. A porous 3-D graphene structure for use as a porous wick medium in a thermal system to enhance thermal performance.

2. The porous 3-D graphene structure of claim 1, wherein pores of the 3-D graphene structure have pore sizes ranging from 1 μm to 1000 μm.

3. The porous 3-D graphene structure of claim 1, having porosity in the range of 30% to 99% by volume.

4. The porous 3-D graphene structure of claim 3, having a minimum of 93% porosity by volume.

5. The porous 3-D graphene structure according to claim 1, wherein the porous 3-D graphene structure is fabricated in aerogel, foam or sponge forms.

6. The porous 3-D graphene structure according to claim 1, wherein the porous 3-D graphene structure has a certain thickness between 1 nm to hundreds of micrometers.

7. The porous 3-D graphene structure according to claim 1, wherein the porous 3-D graphene structure has thermal conductivity of k>2000 W/m·K.

8. The porous 3-D graphene structure according to claim 1, wherein the thermal system is a vapor chamber or heat pipe used in an electronic device.

9. A vapor chamber, comprising:
a metallic housing;
a porous wick medium coated on the inside walls of the metallic housing,
wherein the porous wick medium comprises a 3-D graphene structure.

10. The vapor chamber of claim 9, wherein the 3-D graphene structure has pore sizes ranging from 1 μm to 1000 μm.

11. The vapor chamber of claim 9, wherein the 3-D graphene structure has a porosity in the range of 30% to 99% by volume.

12. The vapor chamber of claim 11, wherein the 3-D graphene structure (102) has a minimum of 93% porosity by volume.

13. The vapor chamber according to claim 9, wherein the 3-D graphene structure being fabricated in aerogel, foam or sponge forms.

14. The vapor chamber according to claim 9, wherein the 3-D graphene structure has a certain thickness between 1 nm to hundreds of micrometers.

15. The vapor chamber according to claim 9, wherein the 3-D graphene structure has a thermal conductivity of k>3000 W/m·K.

16. The vapor chamber according to claim 9, wherein the metallic housing is a conductive material.

17. The vapor chamber according to claim 9, wherein the metallic housing is divided into a plurality of chambers with at least one pillar.

18. The vapor chamber according to claim 9, wherein an internal volume of the metallic housing is divided into a plurality of chambers by 3-D graphene structure with a secondary thickness connecting to the 3-D graphene structure with the primary thickness.

19. The vapor chamber according to claim 16, wherein the conductive material is copper, aluminum or tungsten.
